(19) United States
(12) Patent Application Publication
(10) Pub. No.: US 2022/0291072 A1
(43) Pub. Date: Sep. 15, 2022

(54) OPTICAL LIQUID COOLANT LEAK DETECTOR

(71) Applicant: DELL PRODUCTS, LP, Round Rock, TX (US)

(72) Inventors: Michael Stumpf, Cedar Park, TX (US); Sandor Farkas, Round Rock, TX (US)

(21) Appl. No.: 17/197,298

(22) Filed: Mar. 10, 2021

(51) Int. Cl. G01M 3/22; H05K 7/20

(52) U.S. Cl. CPC G01M 3/226; H05K 7/20781; H05K 7/20836

(57) ABSTRACT

An information handling system includes a liquid cooling system and a coolant leak detector. The liquid cooling system circulates chilled coolant liquid to a component of the information handling system. The coolant liquid includes a fluorescent dye that emits light at a particular wavelength when the fluorescent dye is illuminated. The coolant leak detector system includes a light source, and a detector configured to detect light at the first wavelength. When the liquid cooling system develops a leak, the light source illuminates the first fluorescent dye in the leaked coolant liquid, the detector detects the light at the first wavelength, and the coolant leak detector provides an indication that the liquid cooling system has developed a leak in response to detecting the light at the first wavelength.

### FIELD OF THE DISCLOSURE

This disclosure generally relates to information handling systems, and more particularly relates to optical liquid coolant leak detection in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An information handling system may include a liquid cooling system and a coolant leak detector. The liquid cooling system may circulate chilled coolant liquid to a component of the information handling system. The coolant liquid may include a fluorescent dye that emits light at a particular wavelength when the fluorescent dye is illuminated. The coolant leak detector system may include a light source, and a detector configured to detect light at the first wavelength. When the liquid cooling system develops a leak, the light source may illuminate the first fluorescent dye in the leaked coolant liquid, the detector may detect the light at the first wavelength, and the coolant leak detector may provide an indication that the liquid cooling system has developed a leak in response to detecting the light at the first wavelength

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIGS. 1-5 are block diagrams illustrating an information handling system according to an embodiment of the current disclosure;

FIG. 6 is a block diagram illustrating an large area leak detection system according to another embodiment of the current disclosure; and

FIG. 7 is a block diagram illustrating a generalized information handling system according to another embodiment of the current disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

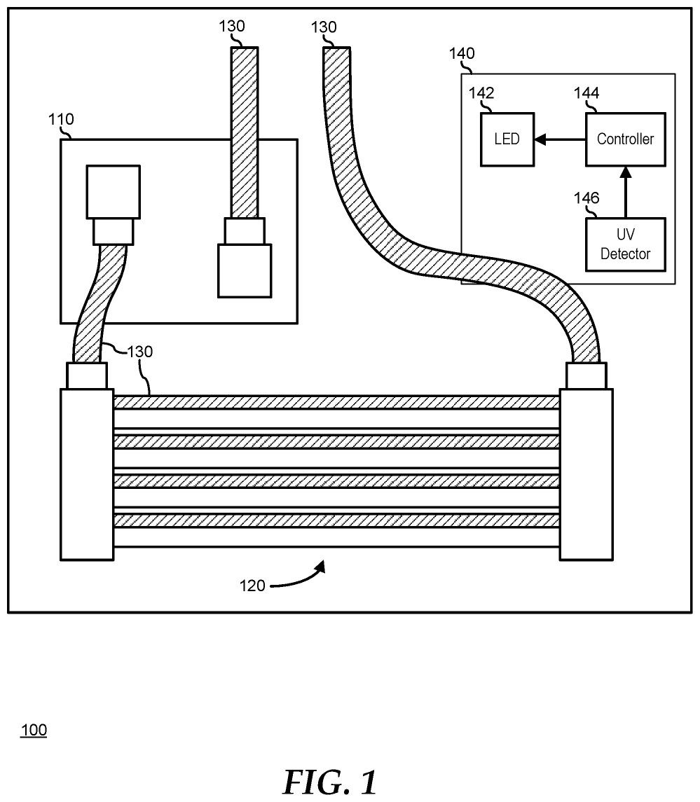

FIGS. 1-5 illustrate an information handling system 100 including a component, 110, memory devices 120, a liquid cooling system 130, and a coolant detection system 140. Information handling system 100 represents a computer system, such as a laptop computer, a desktop computer, a computer workstation, a server system, a blade server system, or other rack-mounted computer equipment, such as a storage server, a network server, a network switch/router, or other datacenter computer equipment, or other electronic equipment generally defined, but being characterized as including a liquid cooling system, as described below. As such, the inclusion of component 120 and memory devices 120 may be understood to represent devices within information handling system 100 that utilize liquid cooling to maintain the devices within a desired operating temperature range. In this regard, liquid cooling system 130 represents various cooling headers, heat exchangers, coolant pumps, controllers, piping and coolant routing elements, such as coolant tubes, pipes, fittings, and the like, coolant reservoirs or other elements that may be typically associated with a liquid cooling system. Here, the various elements of liquid cooling system 130 may be understood to be contained within information handling system 100, or one or more of the elements of the liquid cooling system may be understood to be external to the information handling system, as needed or desired. The details of providing liquid cooling to components within an information handling system are known in the art, and will not be further described herein, except as needed to illustrate the current embodiments.

It has been understood by the inventors of the current disclosure that, with the increased use of liquid cooling in information handling systems and the increasing complexity of such liquid cooling systems, the likelihood of the liquid cooling system developing a leak is likewise increasing. In particular, leaks can be created when various elements of the liquid cooling system develop pinhole leaks in tubing or piping, when fittings are misaligned or worn out, when heat exchangers or cold plates are misaligned, or via other mechanisms as may occur to permit the coolant to leak from the liquid cooling system. Further, in dense computing environments such as server racks, a leak in one element may drip down into another element. Various leak detection schemes are available, based upon the physical contact of the leaking coolant with a leak detector, or the like. However, such systems must be integrated into the mother board of the information handling system, are not typically configured to detect leaks all across the motherboard, and do not scale to larger systems.

Coolant detection system 140 includes a light emitting diode LED 142, a controller 144, and a detector 146. Coolant detection system 140 operates to detect leaked coolant within information handling system 100. In particular, coolant detection system 140 operates in conjunction with coolant liquid from liquid cooling system 130. Here, the coolant liquid contains a dye that fluoresces at a known wavelength when illuminated. Detector 146 may be configured to detect light emissions at the same known wavelength, or may be configured to detect a wide spectrum of light, as needed or desired. Controller 144 activates LED 142 to shine onto the components of information handling system 100, and to a receive detection signal from detector 146. In a particular embodiment, controller 144 activates LED 142 to emit pulses of light in a known pulse pattern. The pulse pattern may be provided at a particular frequency, with a particular duty cycle, or as a more complex pulse pattern, as needed or desired. It will be understood that in other embodiments, controller 144 may activate LED 142 to emit a constant light emission, as needed or desired. LED 142 may represent an ultraviolet LED or another LED that emits a wide spectrum of light, as needed or desired. In either case, the fluorescent die may be selected such that the known wavelength of light is emitted when illuminated by the spectrum of light emitted by LED 142.

When controller 144 receives the detection signal from detector 146, the controller operates to determine if the signal includes the pulse pattern. By utilizing the pulse pattern, controller 144 can distinguish between light detected by detector 146 from other light sources of information handling system 100, such as various LED indicators, cosmetic lights, ambient light from the area surrounding the information handling system, or other types of light sources, and light that is being reflected from the fluorescent dye contained in the coolant. When coolant is detected, controller 144 operates to provide an indication of the presence of coolant liquid within information handling system 100. Such an indication may be provided to a general purpose I/I (GPIO) of information handling system 100 that is associated with a BIOS or OS driver of the information handling system, or that is associated with a baseboard management controller of the information handling system, as needed or desired.

Detector 140 may be integrated into a motherboard of information handling system 100, or another printed circuit board (PCB) that is integrated into the design of the information handling system, or may be a stand-alone device that may be separately affixed to the information handling system, such as to an internal partition, to a side, to a cover, or the like. It will be understood that information handling system 100 may include more than one coolant detection system similar to coolant detection system 140, where the additional coolant detection system is placed to maximize the coverage of the components of the information handling system, as needed or desired. The details of providing a pulse pattern for an LED, detecting the pulse pattern from a detector signal, and other aspects of signal generation and detection are known in the art and will not be further described herein, except as needed to illustrate the current embodiments.

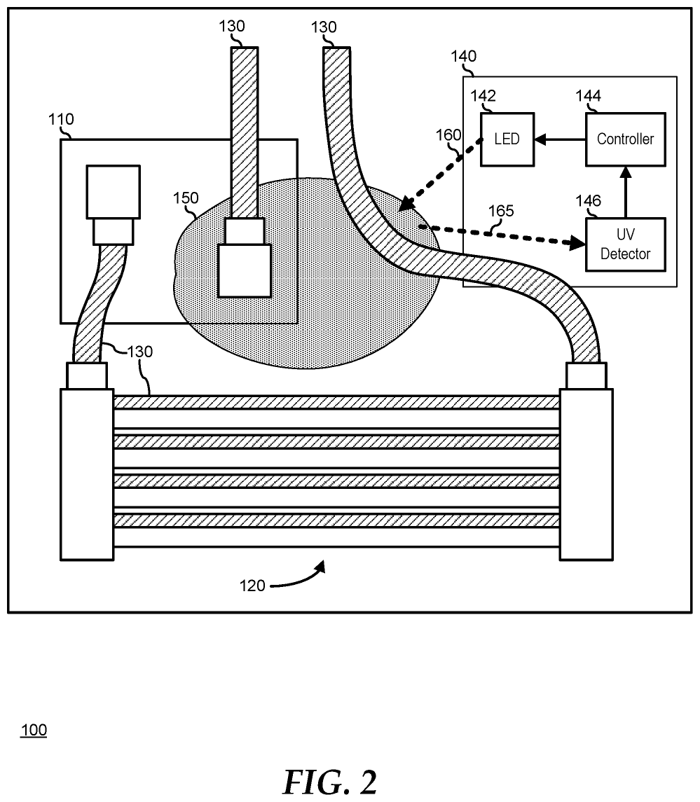

FIG. 2 illustrates information handling system 100 with a coolant leak 150. Here LED 142 emits a pulse pattern of light 160 onto the elements of information handling system 100, and particularly onto coolant leak 150. The fluorescent dye contained in the coolant liquid fluoresces with the same pulse pattern, and the emitted light from the coolant liquid is received by detector 146 and detected by controller 144. In a particular case, the detection may be simplified by choosing detector 146 such that it is only sensitive in a narrow band of wavelengths close to the fluorescing wavelength of the dye, or the detector may be provided with a pre-filter that only permits light at the fluorescing wavelength to be passed to the detector. In this way, controller 144 may not need more complex signal processing capabilities, but may interpret a detection signal from detector 146 as being from the presence of liquid coolant because light at other wavelengths are not similarly detected by the detector.

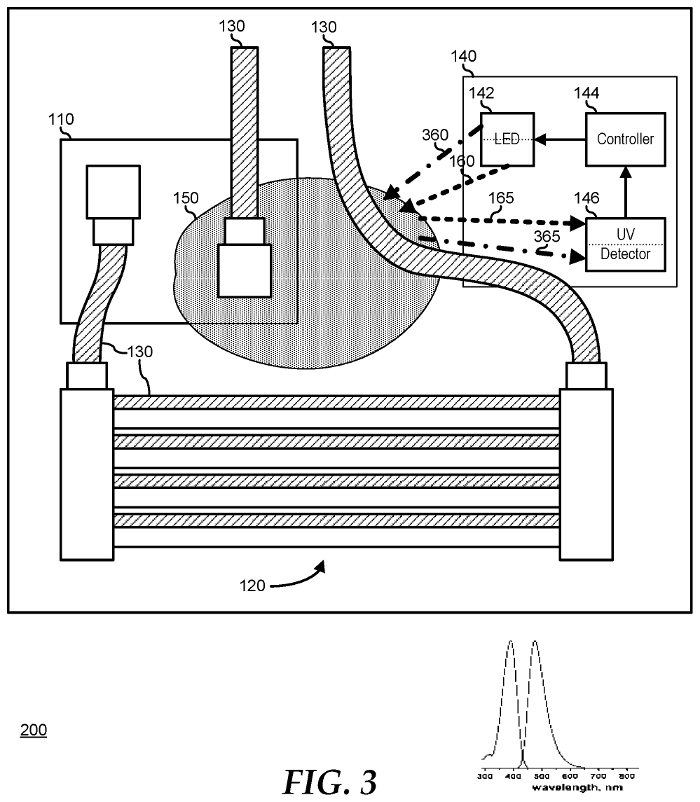

FIG. 3 illustrates information handling system 100 with coolant leak 150, where the coolant liquid contains two dyes that each fluoresce at different known wavelengths when illuminated, as illustrated in the inset graph showing the optical emission of the two dyes at different peak wavelengths. In the illustrated embodiment, either LED 142 or detector 146 may represent two different LEDs or detectors, as indicated by the dotted line dividing the LED and the detector. Here, controller 144 first activates LED 142 to emit pulses of light in a first known pulse pattern 160, and then activates the LED to emit pulses of light in a second known pattern 360. In the case with two LEDs, each LED may be configured to emit light in a different spectrum that is chosen to cause one of the two dyes to fluoresce. In this case, a single detector 146 will receive the light 165 in the first pattern from the first dye, and receive the light 365 in the second pattern from the second dye.

Controller 144 then operates to extract the first and second patterns from the detector signal to determine the presence of leaked coolant liquid. In particular, controller 144 will determine whether or not both patterns are detected. If not, then no leaked coolant liquid is detected, and only when both pattern are extracted is a coolant liquid leak detected. In the case with two detectors, each detector may be configured to detect the light from one of the two dyes. Then controller 144 operates to extract the first pattern from the first detector and the second pattern from the second detector. Then, as above, the extraction of both the first and second patterns by controller 144 provides the detection of the leaked coolant liquid. In either case, other components of information handling system 100 which might similarly fluoresce at one or the other wavelengths of the two dyes will not cause a false indication of a leak.

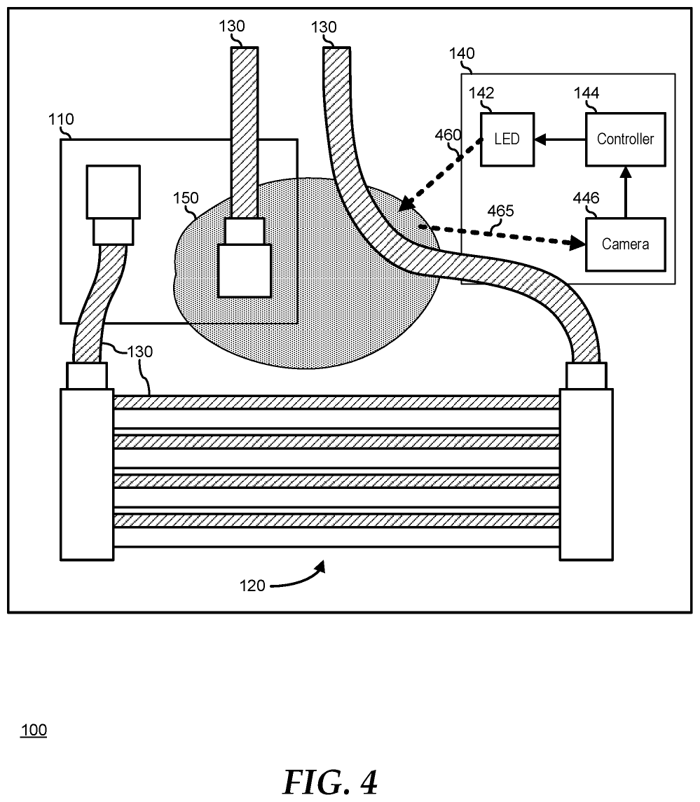

FIG. 4 illustrates another embodiment of information handling system 100 with coolant leak 150, where detector 146 is replaced with a camera 446. Camera 446 represents a CMOS camera or other photographic detector such as a charge-coupled device (CCD) array or the like, that is configured to receive full picture images, as opposed to the on-off/intensity information received from detector 144. Here, controller 144 will be understood to provide greater functionality, such as video image processing and the like. For example, controller 144 operates to mask known light sources within information handling system 100 from consideration when determining the presence of leaked coolant liquid. Further, controller 144 operates to detect the motion of the leaked coolant liquid as the liquid spreads within information handling system 100. Further, by where the leaked coolant liquid was first detected, controller 144 operates to provide an indication as to the source of the leak. In a particular embodiment, a detector similar to detector 140 with camera 446 is placed outside of information handling system 100 to detect externally sourced leaks, to detect that the extend of a leak has grown outside of the information handling system, or for other leak detection as needed or desired.

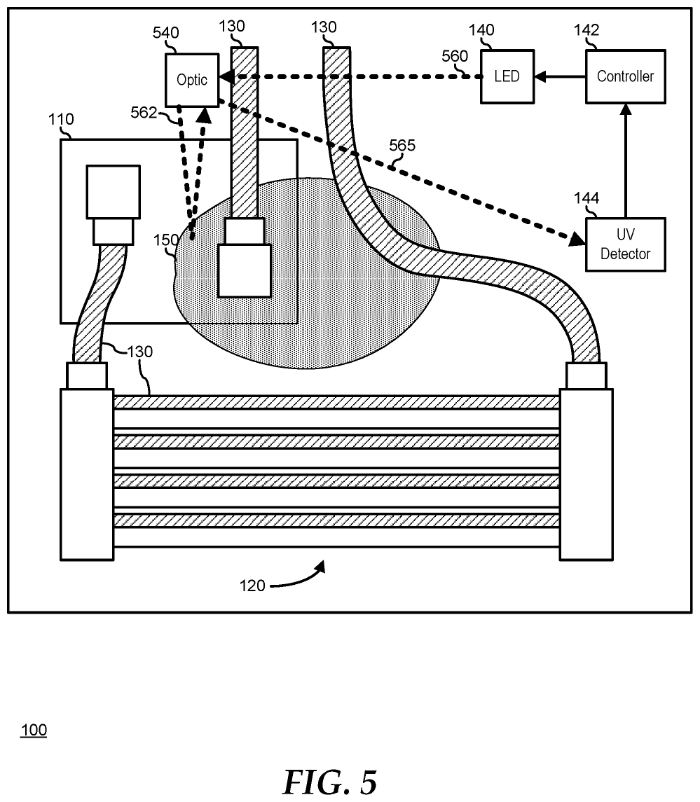

FIG. 5 illustrates the another embodiment of information handling system 100 with coolant leak 150, where the functionality of detector 140 is extended by the addition of optical element 540. Optical element 540 operates to extend the range of detector 140, to increase the resolution of the detector, to increase the coverage of the detector, or the like. While detector 140 is illustrates as including detector 140, the use of optic element 540 is not limited to a detector, but may likewise be utilized with a camera device such as camera 446, as needed or desired. Optical element 540 represents a wide variety of optical devices, such as a Fresnel mirror, a light pipe, a reflective sticker or tape, a wide angle lens, a collimating lens, or the like. A Fresnel mirror reflects light perpendicularly to the direction of incidence, and may be utilized to shine the light from LED 142 downward onto the planar surface of information handling system 100, or may be utilized to focus the reflected light onto detector 146.

A light pipe operates to direct the light from LED 142 to a particular location on information handling system 100, such as in tight spaces like the spaces between DIMMs, under a heat exchanger, or the like. A reflective sticker or tape may be used on a partition wall, a side, or a cover of information handling system 100 to make those surfaces more reflective. A wide angle lens may be used to provide greater coverage of detector 140. A collimating lens may be used to straighten light, for example to extend the range of detector 140. Other optical devices may be utilized as needed or desired. In a particular embodiment, optical element 540 may be located outside of information handling system 100 to extend the coverage of leak detector 140 to outside of the information handling system.

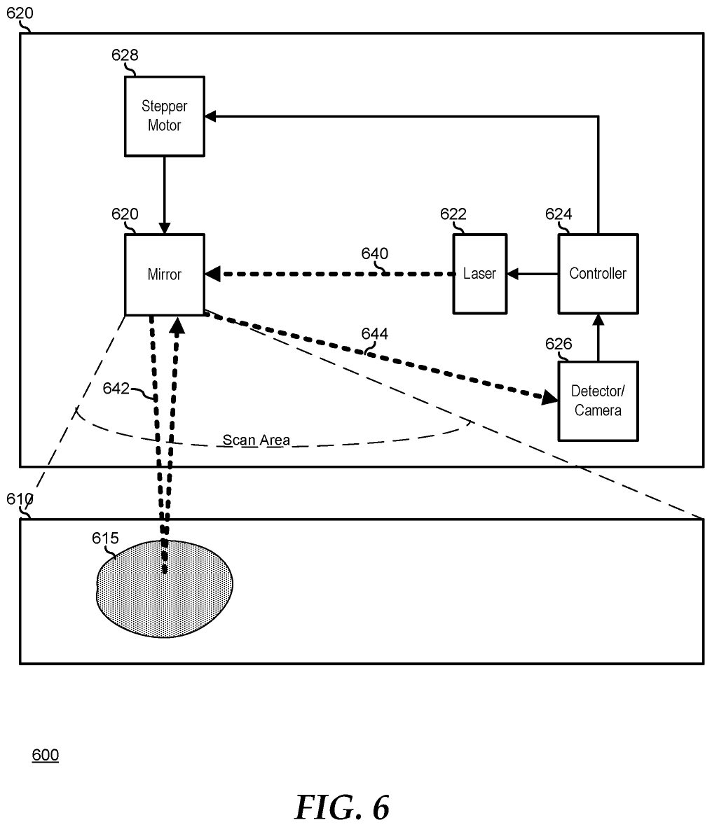

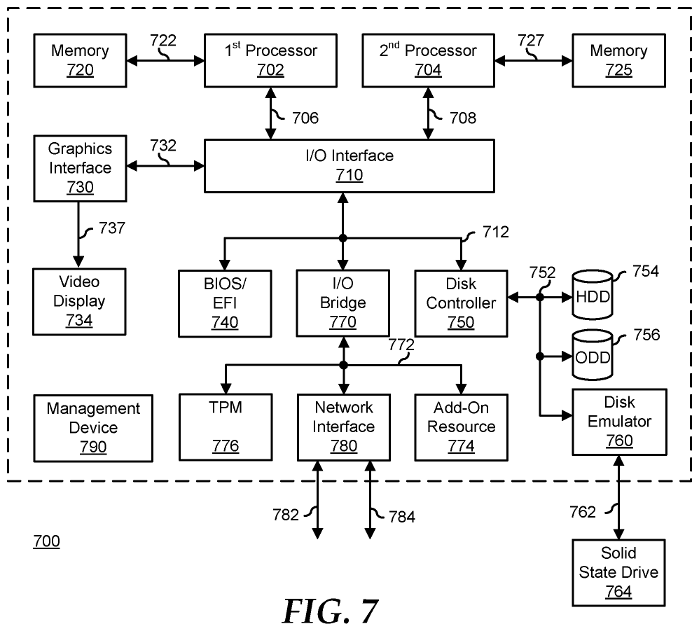

FIG. 6 illustrates a large area coolant leak detector system 600 including a detection area 610 and a coolant leak detector 620. Coolant leak detector 620 represents a coolant leak detector adapted to detect coolant leaks in large areas, such as a datacenter floor or other are with a large number of components that are chilled using a liquid cooling system. Coolant leak detector 620 includes a UV laser 622, a controller 624, a detector/camera 626, a stepper motor 628, and a mirror 630. Laser 622, controller 624, and detector/camera 626 operate together similarly to the elements of coolant leak detector 140 as described above with respect to FIGS. 1-5, and each embodiment described therein may be ascribed to coolant leak detector 620. As such, coolant leak detector 620 may be understood to likewise include optical elements similar to optical element 540, as needed or desired. Here, mirror 630 is mechanically attached to stepper motor 628 such that actuation of the stepper motor operates to reorient the mirror.

Laser 622 is aimed at mirror 630 and the laser light 640 is reflected 642 onto the surfaces of detection area 610. Then, by sequentially actuating stepper motor 628 to reorient mirror 630, the laser light is swept across the surface of the large area, thereby scanning detection area 610 for liquid coolant leaks. When the scanned laser light shines on coolant leak 615, the coolant fluoresces and is reflected by mirror 620 back to detector/camera 626 to detect the coolant leak.

In a particular embodiment, laser 622 represents a LED or LED array with sufficient light power to scan detection area 610, and may include a collimating lens, as needed or desired. In another embodiment, stepper motor 628 represents a linear- or rotational-actuator, such that the motion imparted to mirror 620 is a rotation, and the resulting scan area is more or less linear. Here, mirror 620 may be understood to include an optical element that broadens the light beam 640 into a wider coverage, such that the linear scanning resulting from the motion of mirror 620 results in a 2-dimensional scan of detection area 610. In another embodiment, stepper motor 628 represents a device configured to impart two dimensions of motion to mirror 630. Here, the light beam 640 remains a point scan, but by sequentially moving mirror through a first range of motion, and then sequentially setting a new orientation for the second range of motion and sequentially moving the mirror through the first range of motion again, a 20 dimensional scan pattern is achieved. In a particular embodiment, controller 624 activates stepper motor 628 to skip through selected orientations, thereby effectively blocking, or masking portions of detection area 610 from being scanned. For example, controller 624 can limit the scan area to areas below eye-height, or the like.

In a particular embodiment, multiple leak detectors are employed in an information handling system or detection area, as needed or desired. Here a wide variety of topologies are possible, such as where one controller controls one or more LED or laser, one or more detector or camera, one or more stepper motor, or a combination thereof. Further, multiple controllers may be provided. Here, each controller may have a detection signal, such as a one-wire signal, where each detection signal is provided to a GPIO of an information handling system or BMC, or where the detection signals are ganged together, for example in a wired-or topology. In another case, each controller may have a higher bandwidth interface capable of providing video information as needed or desired. In another embodiment, one or more information handling system may each include its own leak detector that provides its output to, for example, a datacenter management system, as needed or desired. In another embodiment, a leak detector is manufactured as an add-in module that can be added to an existing information handling system or detection area to provide a leak detection capability, or to upgrade and existing leak detection system, as needed or desired.

FIG. 6 illustrates a generalized embodiment of an information handling system 700. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable medium for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below, and operates to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756 , a disk emulator 760 connected to an external solid state drive (SSD) 762, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756 , disk emulator 760, SSD 762, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708. Memory 720 is connected to processor 702 via a memory interface 722. Memory 725 is connected to processor 704 via a memory interface 727. Graphics interface 730 is connected to I/O interface 710 via a graphics interface 732, and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 1394 (Firewire) interface, a proprietary interface, or a combination thereof Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712, or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof. Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700. Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An information handling system, comprising:
a liquid cooling system configured to circulate chilled coolant liquid to a component of the information handling system, wherein the coolant liquid includes a first fluorescent dye that emits light at a first wavelength when the first fluorescent dye is illuminated; and
a coolant leak detector system including a light source and a detector, the detector configured to detect light at the first wavelength, wherein when the liquid cooling system develops a leak, the light source illuminates the first fluorescent dye in the leaked coolant liquid, the detector detects the light at the first wavelength, and the coolant leak detector provides an indication that the liquid cooling system has developed a leak in response to detecting the light at the first wavelength.

2. The information handling system of claim 1, wherein the coolant leak detector further includes a controller coupled to the detector, and wherein the controller is configured to provide the indication.

3. The information handling system of claim 2, wherein the controller is coupled to the light source, and wherein the controller is further configured to activate the light source, wherein in activating the light source, the light source emits light in a first pattern.

4. The information handling system of claim 3, wherein in detecting the light at the first wavelength, the detector further detects the light in the first pattern.

5. The information handling system of claim 1, wherein the coolant liquid further includes a second fluorescent dye that emits light at a second wavelength different from the first wavelength when the second fluorescent dye is illuminated.

6. The information handling system of claim 5, wherein, when the liquid cooling system develops the leak, the detector detects the light at the second wavelength, and wherein providing the indication that the liquid cooling system has developed the leak is further in response to detecting the light at the second wavelength.

7. The information handling system of claim 1, wherein the detector comprises a camera.

8. The information handling system of claim 7, wherein the coolant leak detector determines a source of the leak based upon the camera.

9. The information handling system of claim 1, further comprising:
an optical device configured to modify the light emitted from the light source.

10. The information handling system of claim 8, wherein the optical device includes at least one of a Fresnel mirror, mirror, a light pipe, a reflective sticker, a reflective tape, a wide angle lens, and a collimating lens,

11. A method, comprising:
circulating a chilled coolant liquid to a component of an information handling system, wherein the coolant liquid includes a first fluorescent dye that emits light at a first wavelength when illuminated;
illuminating, by a light source, the first fluorescent dye;
detecting, by a detector, the light at the first wavelength; and
providing an indication that the liquid cooling system has developed a leak in response to detecting the light at the first wavelength.

12. The method of claim 11, wherein the detector further includes a controller coupled to the detector, and wherein the controller is configured to provide the indication.

13. The method of claim 12, wherein the controller is coupled to the light source, and the method further comprises activating, by the controller, the light source, wherein in activating the light source, the light source emits light in a first pattern.

14. The method of claim 13, wherein in detecting the light at the first wavelength, the detector further detects the light in the first pattern.

15. The method of claim 11, wherein the coolant liquid further includes a second fluorescent dye that emits light at a second wavelength different from the first wavelength when the second fluorescent dye is illuminated.

16. The method of claim 15, wherein when the liquid cooling system develops the leak, the method further comprises detecting the light at the second wavelength, wherein providing the indication that the liquid cooling system has developed the leak is further in response to detecting the light at the second wavelength.

17. The method of claim 11, wherein the detector comprises a camera.

18. The method of claim 1, further comprising modifying, by an optical device, the light emitted from the light source.

19. The method of claim 18, wherein the optical device includes at least one of a Fresnel mirror, mirror, a light pipe, a reflective sticker, a reflective tape, a wide angle lens, and a collimating lens,

20. A coolant leak detection system to detect leaked coolant liquid, wherein the coolant liquid includes a first fluorescent dye that emits light at a first wavelength when the first fluorescent dye is illuminated, the coolant leak detection system comprising:
a light source; and
a detector configured to detect light at the first wavelength, wherein the light source illuminates the first fluorescent dye in the leaked coolant liquid, the detector detects the light at the first wavelength, and the coolant leak detection system provides an indication that the liquid cooling system has developed a leak in response to detecting the light at the first wavelength.
